(19) United States
(12) Patent Application Publication
(10) Pub. No.: US 2005/0009346 A1
(43) Pub. Date: Jan. 13, 2005

(54) Method of manufacturing semiconductor device

(75) Inventor: Takashi Miyajima, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., TOKYO (JP)

(21) Appl. No.: 10/724,224

(22) Filed: Dec. 1, 2003

(30) Foreign Application Priority Data
Jul. 8, 2003 (JP) 2003-193464

(51) Int. Cl. H01L 21/302; H01L 21/461

(52) U.S. Cl. 438/689

(57) ABSTRACT

Wet etching is performed on a storage electrode (7) made of ruthenium from above using periodic acid or a cerium ammonium nitrate solution. By using that kind of etching liquid, ruthenium as well as oxide films formed on the surface of the storage electrode (7) can be etched, causing the surface of the storage electrode (7) to be entirely etched. As a result, needle projections having been formed on the top surface of the storage electrode (7) are removed, rounding the top ends of the storage electrode (7). Consequently, the thickness of a dielectric film of a DRAM capacitor to be formed on the storage electrode (7) can be easily made uniform, allowing a reduction in leakage current of the capacitor.

### BACKGROUND OF THE INVENTION

1. Field of the Invention

The present invention relates to a method of manufacturing a semiconductor device having a capacitor.

2. Description of the Background Art

With higher integration of a semiconductor device, the dimensions of a semiconductor chip have been reduced, and the dimensions of and spacing between storage electrodes (also referred to as “storage node”) of a capacitor included in a semiconductor memory have become smaller. The development of such a semiconductor memory having a semiconductor chip of small dimensions requires an increase in capacity of a capacitor. To meet this need, a semiconductor memory including an MIM (Metal-Insulator-Metal) capacitor has been proposed that adopts a high melting point metal material such as ruthenium (Ru) for an electrode material and adopts a high dielectric film such as tantalum pentoxide for a dielectric film. The following patent documents 1 through 5 disclose a semiconductor device having a capacitor and its manufacturing method.

(Patent Document 1) Japanese Patent Application Laid Open No. 2002-198498,

(Patent Document 2) Japanese Patent Application Laid Open No. 2002-124649,

(Patent Document 3) Japanese Patent Application Laid Open No. 2001-210805,

(Patent Document 4) Japanese Patent Application Laid Open No. 8-70106 (1996), and

(Patent Document 5) Japanese Patent Application Laid Open No. 2000-58795.

When an MIM capacitor as the aforementioned one is manufactured, a leakage current may increase depending on the manufacturing methods.

### SUMMARY OF THE INVENTION

It is an object of the present invention to provide a technique capable of reducing a leakage current of a capacitor.

According to the present invention, a first method of manufacturing a semiconductor device including a capacitor having a storage electrode, a dielectric film and a plate electrode includes the following steps (a) to (g). The step (a) is to form an insulating film. The step (b) is to form a plurality of openings in the insulating film that open toward an upper surface of the insulating film. The step (c) is to form a film of an electrode material made of metal on a surface of each of the openings and the upper surface of the insulating film. The step (d) is to etch back the electrode material by performing dry etching thereon, to form a storage electrode made of the electrode material in each of the openings. The step (e) is to perform wet etching on the storage electrode. The step (f) is to form a dielectric film on the storage electrode after the step (e). The step (g) is to form a plate electrode on the dielectric film.

Since the wet etching is performed on the storage electrode, needle projections that may be generated on the storage electrode by performing the dry etching on the electrode material can be removed by the wet etching. Therefore, the dielectric film can be easily formed uniformly on the storage electrode, allowing a reduction in leakage current of the capacitor.

According to the present invention, a second method of manufacturing a semiconductor device including a capacitor having a storage electrode, a dielectric film and a plate electrode includes the following steps (a) to (g). The step (a) is to form an insulating film. The step (b) is to form a plurality of openings in the insulating film that open toward an upper surface of the insulating film. The step (c) is to form a film of an electrode material made of metal on a surface of each of the openings and the upper surface of the insulating film. The step (d) is to perform heat treatment in a hydrogen atmosphere on the electrode material. The step (e) is to etch back the electrode material by performing dry etching thereon, to form a storage electrode made of the electrode material in each of the openings after the step (d). The step (f) is to form a dielectric film on the storage electrode. The step (g) is to form a plate electrode on the dielectric film.

Since heat treatment is performed in a hydrogen atmosphere on the electrode material, oxide films that may be formed on the surface of the electrode material when being formed can be reduced with hydrogen and removed. Further, because grains of a metal composing the electrode material can be enlarged, oxide films resist being formed on the surface of the electrode material when the dry etching is performed on the electrode material. Therefore, the electrode material can be etched fairly uniformly, preventing the needle projections from being formed on the top surface of the storage electrode. Consequently, the thickness of the dielectric film can be made uniform, allowing a reduction in leakage current of the capacitor.

According to the present invention, a third method of manufacturing a semiconductor device including a capacitor having a storage electrode, a dielectric film and a plate electrode includes the following steps (a) to (h). The step (a) is to form an insulating film. The step (b) is to form a plurality of openings in the insulating film that open toward an upper surface of the insulating film. The step (c) is to form a film of an electrode material made of metal on a surface of each of the openings and the upper surface of the insulating film. The step (d) is to polish the electrode material from above with an abrasive to remove the electrode material lying on the upper surface of the insulating film, thereby forming a storage electrode made of the electrode material in each of the openings. The step (e) is to remove the abrasive that adheres to a structure obtained by performing the step (d). The step (f) is to perform heat treatment in a hydrogen atmosphere on a structure obtained by performing the step (e). The step (g) is to form a dielectric film on the storage electrode after the step (f). The step (h) is to form a plate electrode on the dielectric film.

Since heat treatment is performed in a hydrogen atmosphere after forming the storage electrode, oxide films that are formed on the surface of the storage electrode can be reduced and removed, causing migration in a metal composing the storage electrode. Consequently, even when a clearance is created between the storage electrode and the insulating film due to partial removal of the insulating film when the abrasive is removed in the step (e), the storage electrode can be altered in shape by the caused migration in the storage electrode, bringing the insulating film and the storage electrode in tight contact to each other. Therefore, the above clearance is eliminated, allowing a reduction in leakage current of the capacitor.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 through 6 are sectional views showing a method of manufacturing a semiconductor device in the order of process steps according to a first preferred embodiment of the present invention;

FIGS. 7 through 9 are sectional views showing a method of manufacturing a semiconductor device in the order of process steps according to a second preferred embodiment of the invention; and

FIGS. 10 through 13 are sectional views showing a method of manufacturing a semiconductor device in the order of process steps according to a third preferred embodiment of the invention.

### DESCRIPTION OF THE PREFERRED EMBODIMENTS

### First Preferred Embodiment

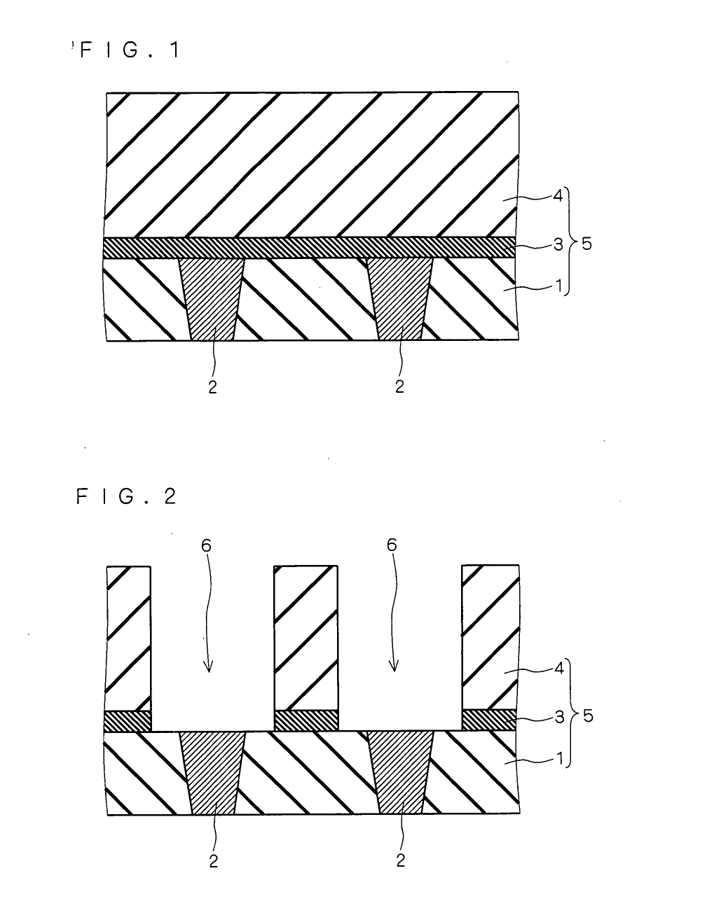

FIGS. 1 through 6 are sectional views showing a method of manufacturing a semiconductor device in the order of process steps according to a first preferred embodiment of the invention. The semiconductor device according to the first preferred embodiment includes a DRAM having an MIM capacitor, for example, as a capacitor of a memory cell. The method of manufacturing the semiconductor device according to the present embodiment will now be described referring to FIGS. 1 through 6.

As shown in FIG. 1, a semiconductor substrate (not shown) having a plurality of MOS transistors of a DRAM memory cell formed thereon is provided, and an interlayer insulating film 1 is provided above the substrate. Then, contact plugs 2 each electrically connected to either one of source and drain regions of each of the MOS transistors are formed inside the interlayer insulating film 1. The interlayer insulating film 1 is a BPTEOS film having a thickness of 450 nm, for example, and the contact plugs 2 are a stacked film composed of a titanium nitride film and a tungsten film, for example.

To form the contact plugs 2, a resist (not shown) having a predetermined opening pattern is first formed on the interlayer insulating film 1. Next, the interlayer insulating film 1 is etched with the resist as a mask to form a plurality of contact holes (not shown) in the interlayer insulating film 1 that penetrate the interlayer insulating film 1 in the thickness direction. Next, a titanium nitride film is entirely formed by a CVD method, and a tungsten film to fill each of the contact holes is entirely formed afterwards by the CVD method. Then, the titanium nitride film and the tungsten film lying above the contact holes are removed by a CMP method. As a result, the plurality of contact plugs 2 that are made of a titanium nitride film and a tungsten film and have the upper surfaces not covered by and exposed from the interlayer insulating film 1 are formed in the interlayer insulating film 1.

Next, a silicon nitride film 3 and a BPTEOS film 4 are entirely formed in this order. The silicon nitride film 3 has a thickness of 50 nm, for example, and the BPTEOS film 4 has a thickness of 1200 nm, for example. As a result, an insulating film 5 composed of the interlayer insulating film 1, the silicon nitride film 3 and the BPTEOS film 4 is completed with the plurality of contact plugs 2 provided therein.

Thereafter, a resist (not shown) having a predetermined opening pattern is formed on the insulating film 5. Then, dry etching is performed on the BPTEOS film 4 of the insulating film 5 with the resist as a mask and the silicon nitride film 3 as an etching stopper, thereby partially exposing the silicon nitride film 3. Then, the exposed silicon nitride film 3 is removed by dry etching with the resist as a mask again. As a result, as shown in FIG. 2, a plurality of openings 6 are formed in the insulating film 5 that open toward the upper surface of the insulating film 5. The openings 6 expose the upper surfaces of the contact plugs 2 and penetrate the silicon nitride film 3 and the BPTEOS film 4 in their thickness direction.

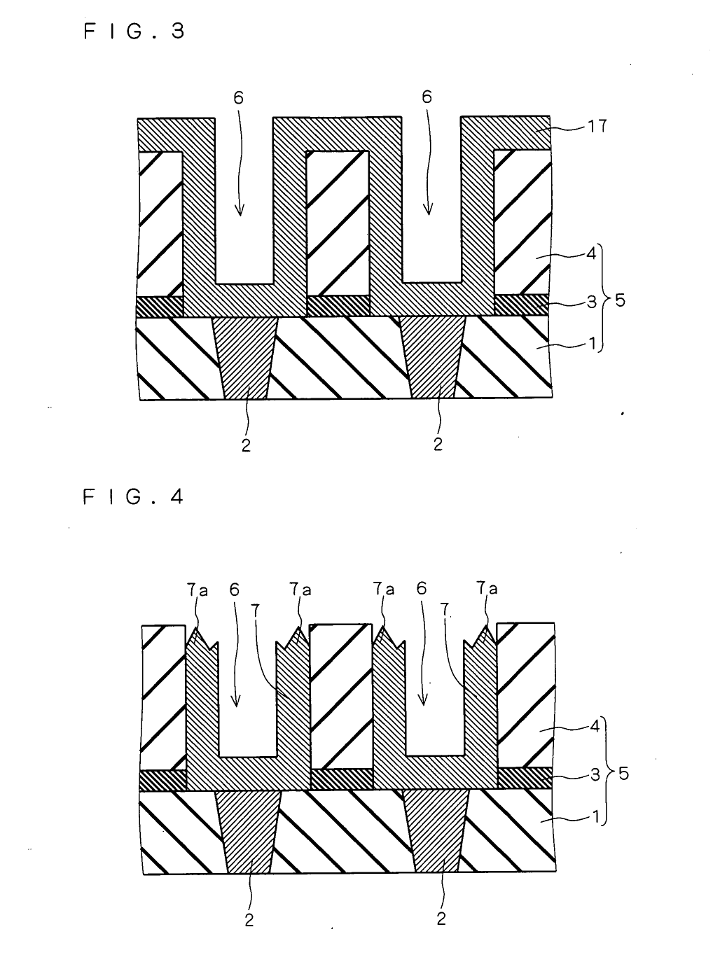

Subsequently, a metal layer (not shown) having a thickness of 20 nm, for example, is entirely formed by a sputtering method. This metal layer is made of ruthenium, for example. Then, as shown in FIG. 3, a low pressure CVD method is performed in an oxygen atmosphere with the metal layer as a seed layer, to entirely form a film of an electrode material 17 which will serve as a storage electrode of a DRAM capacitor in subsequent steps. As a result, the electrode material 17 is formed on the surfaces of the openings 6 and the upper surface of the insulating film 5. The electrode material 17 is made of ruthenium, for example, and has a thickness of 20 to 50 nm, for example. The above low pressure CVD method sets a processing temperature at 400° C. and uses Ru (CP)₂ as a solid state source.

The electrode material 17, which is made of ruthenium, is rendered in an amorphous state by the above low pressure CVD method. Accordingly, grains of ruthenium composing the electrode material 17 are small, which causes minute oxide films (not shown) made of ruthenium oxide (RuO₂) to be formed scatteredly on the surface of the electrode material 17.

Next, each of the openings 6 is filled with a resist (not shown). Then, anisotropic dry etching having a high etching rate in the thickness direction of the insulating film 5 is performed on the electrode material 17 from above with the resist as a mask, to remove the electrode material 17 lying above the openings 6. As a result, the electrode material 17 is etched back, and as shown in FIG. 4, a storage electrode 7 made of the electrode material 17 of the DRAM capacitor is formed in each of the openings 6. Thereafter, the resist in the openings 6 is removed.

The above dry etching for forming the storage electrode 7 uses a mixed gas of chlorine (Cl) and oxygen (O₂) as an etching gas. When the dry etching is performed on the electrode material 17 with the mixed gas, the minute oxide films formed scatteredly on the surface of the electrode material 17 as explained above function as a mask, making the etching on the electrode material 17 hard to partially proceed. Moreover, as the above dry etching etches the electrode material 17 while oxidizing the surface, minute oxide films are formed scatteredly on the surface of the electrode material 17 at the time of the dry etching as well. Accordingly, as shown in FIG. 4, needle projections 7a are formed on the top ends of the storage electrode 7 obtained after being etched back. The thickness of a dielectric film of the DRAM capacitor will be made nonuniform when formed on the storage electrode 7 in this state, resulting in an increase in leakage current of the capacitor. Thus, the first preferred embodiment performs wet etching on the storage electrode 7 to remove the needle projections. This process will now be discussed in detail.

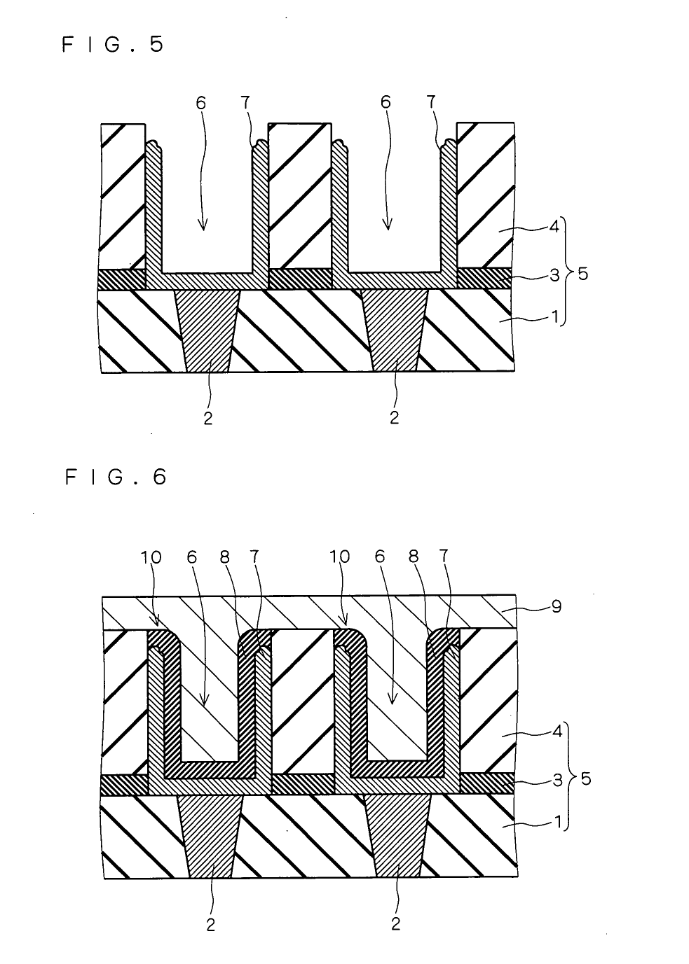

Wet etching is performed on the structure shown in FIG. 4 from above without a mask using periodic acid or a cerium ammonium nitrate solution. By using periodic acid or a cerium ammonium nitrate solution as an etching liquid, ruthenium as well as the oxide films formed on the surface of the storage electrode 7 can be etched, causing the surface of the storage electrode 7 to be entirely etched. Here, the storage electrode 7 is removed a depth of approximately 10 nm from the surface toward the thickness direction. As a result, as shown in FIG. 5, the needle projections 7a having been formed on the top ends of the storage electrode 7 are removed, rounding the top surface of the storage electrode 7. Consequently, the thickness of the dielectric film of the DRAM capacitor to be subsequently formed can be easily made uniform, allowing a reduction in leakage current of the capacitor.

Next, as shown in FIG. 6, a dielectric film 8 of the DRAM capacitor is formed on the storage electrode 7, and a plate electrode 9 of the DRAM capacitor is subsequently formed on the dielectric film 8. Each of the openings 6 is thus filled with the plate electrode 9. The dielectric film 8 is formed by forming an insulating film made of tantalum pentoxide (Ta₂O₂), for example, and having a thickness of 15 nm on the storage electrode 7, and oxidizing and crystallizing the insulating film in an oxygen atmosphere at a temperature of 150° C. The plate electrode 9 is made of ruthenium, for example.

The aforementioned steps complete an MIM capacitor 10 having the storage electrode 7 made of ruthenium, the dielectric film 8 made of tantalum pentoxide, and the plate electrode 9 made of ruthenium.

Thereafter, a BPTEOS film (not shown) is entirely formed, and an aluminum wiring (not shown) is formed thereon. Lastly, a passivation film (not shown) is entirely formed, thereby completing a semiconductor device including a DRAM memory cell having the MIM capacitor 10.

As explained above, in the method of manufacturing the semiconductor device according to the first preferred embodiment, the wet etching is performed on the storage electrode 7. Accordingly, the needle projections 7a that may be generated on the storage electrode 7 by performing the dry etching on the electrode material 17 as in the first preferred embodiment can be removed by the wet etching. Therefore, the dielectric film 8 can be easily formed uniformly on the storage electrode 7, allowing a reduction in leakage current of the MIM capacitor 10.

Moreover, because the wet etching is performed entirely on the surface of the storage electrode 7, an aspect ratio of the openings 6 after forming the storage electrode 7 becomes small when compared with that without wet etching. Accordingly, the quality of step coverage is improved in forming the dielectric film 8 and the plate electrode 9, ensuring the formation of the dielectric film 8 and the plate electrode 9 at the bottom of each of the openings 6. This allows a reduction in leakage current of the MIM capacitor 10.

### Second Preferred Embodiment

FIGS. 7 through 9 are sectional views showing a method of manufacturing a semiconductor device in the order of process steps according to a second preferred embodiment of the invention. The method of manufacturing the semiconductor device according to the present embodiment will now be described referring to FIGS. 7 through 9.

First, the structure shown in FIG. 3 is obtained by the method of manufacturing the semiconductor device according to the aforementioned first preferred embodiment. Next, heat treatment is performed in a hydrogen atmosphere on the structure shown in FIG. 3, for thirty seconds at a temperature of 700° C., for example. The heat treatment in the hydrogen atmosphere reduces the minute oxide films having been formed on the surface of the electrode material 17 with hydrogen and remove them, causing migration in ruthenium composing the electrode material 17. As a result, as shown in FIG. 7, a tip of a corner portion 37 is rounded, the comer portion 37 being formed at a boundary portion between the electrode material 17 lying on the upper surface of the BPTEOS film 4 and the electrode material 17 lying on the inner side surface of the BPTEOS film 4. Besides, the heat treatment in the hydrogen atmosphere enlarges the grains of ruthenium composing the electrode material 17.

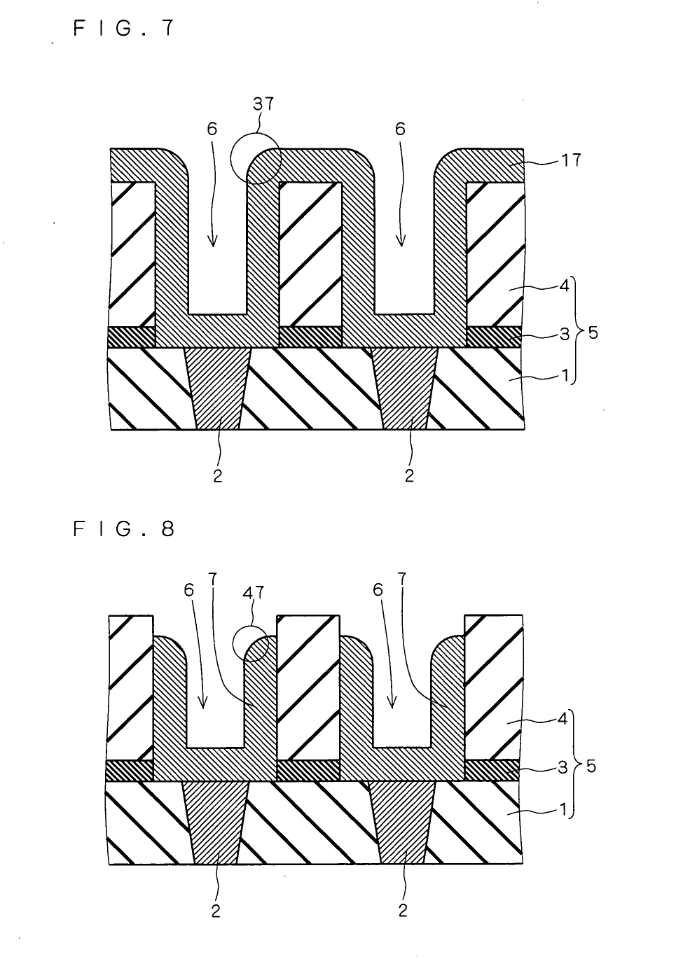

Next, each of the openings 6 is filled with a resist (not shown). Then, anisotropic dry etching having a high etching rate in the thickness direction of the insulating film 5 is performed on the electrode material 17 from above with the resist as a mask, to remove the electrode material 17 lying above the openings 6. As a result, the electrode material 17 is etched back, and as shown in FIG. 8, the storage electrode 7 is formed in each of the openings 6. Thereafter, the resist in the openings 6 is removed.

In the same manner as the first preferred embodiment, the above dry etching for forming the storage electrode 7 uses a mixed gas of chlorine and oxygen as an etching gas. When the dry etching is performed on the electrode material 17, the oxide films having been formed on the surface of the electrode material 17 has been reduced and removed by the above heat treatment in the hydrogen atmosphere. Further, when the dry etching is performed, the grains of ruthenium composing the electrode material 17 have been enlarged, so that oxide films resist being formed on the surface of the electrode material 17. Therefore, the electrode material 17 can be etched fairly uniformly, preventing the needle projections 7a from being formed on the top surface of the storage electrode 7.

Furthermore, since the tip of the comer portion 37 of the electrode material 17 has been rounded by the heat treatment in the hydrogen atmosphere on the electrode material 17, a tip of a corner portion 47 formed at a boundary portion between the top surface and an exposed side surface of the storage electrode 7 is rounded after performing the above dry etching.

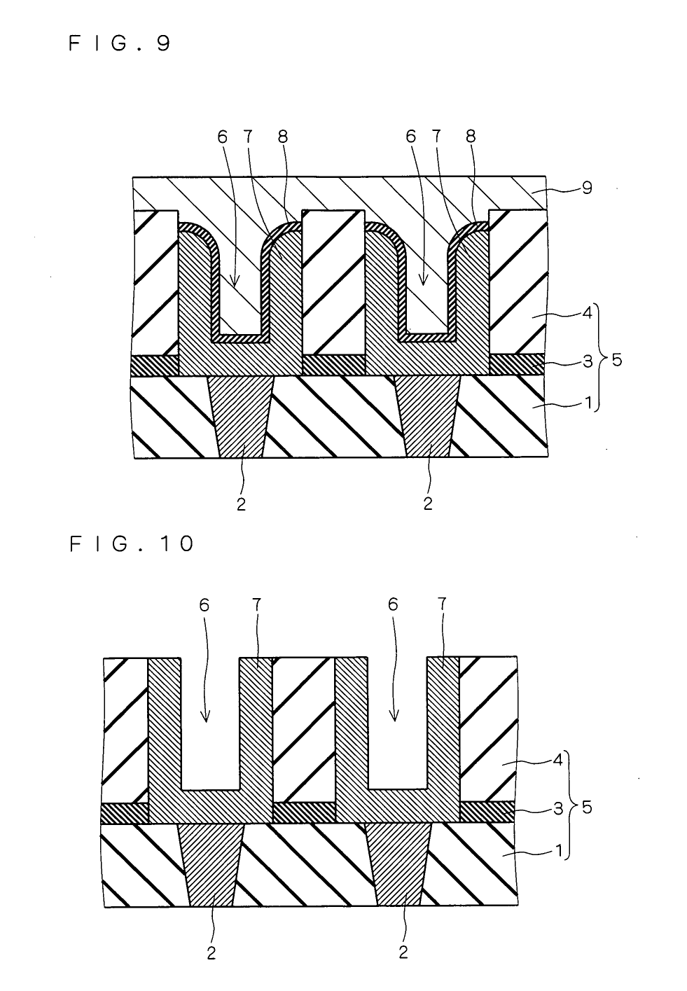

Next, as shown in FIG. 9, in the same manner as the first preferred embodiment, the dielectric film 8 and the plate electrode 9 are successively formed on the storage electrode 7, thereby completing the MIM capacitor 10. Thereafter, in the same manner as the first preferred embodiment, a BPTEOS film, an aluminum wiring and a passivation film all of which are not shown are successively formed, thereby completing a semiconductor device including a DRAM memory cell having the MIM capacitor 10.

As explained above, in the method of manufacturing the semiconductor device according to the second preferred embodiment, heat treatment is performed in a hydrogen atmosphere on the electrode material 17. Accordingly, the oxide films that may be formed on the surface of the electrode material 17 when being formed as in the second preferred embodiment can be reduced with hydrogen and removed. Further, because the grains of ruthenium composing the electrode material 17 can be enlarged, oxide films resist being formed on the surface of the electrode material 17 when the dry etching is performed on the electrode material 17. Therefore, the electrode material 17 can be etched fairly uniformly, preventing the needle projections 7a from being formed on the top surface of the storage electrode 7. Consequently, the thickness of the dielectric film 8 can be made uniform, allowing a reduction in leakage current of the MIM capacitor 10.

Additionally, in the second preferred embodiment, the tip of the comer portion 37 of the electrode material 17 is rounded by the heat treatment in the hydrogen atmosphere. Accordingly, the tip of the comer portion 47 of the storage electrode 7 is rounded by performing the anisotropic dry etching having a high etching rate in the thickness direction of the insulating film 5 on the electrode material 17. Unlike the second preferred embodiment, if the tip of the comer portion 47 of the storage electrode 7 is pointed, the dielectric film 8 resists adhering to the comer portion 47, resulting in the thin dielectric film 8 lying on the comer portion 47. In the manufacturing method according to the second preferred embodiment, the dielectric film 8 easily adheres to the corner portion 47 whose tip has been rounded, ensuring the sufficiently thick dielectric film 8 lying on the comer portion 47. This allows a reduction in leakage current of the MIM capacitor 10.

### Third Preferred Embodiment

FIGS. 10 through 13 are sectional views showing a method of manufacturing a semiconductor device in the order of process steps according to a third preferred embodiment of the invention. The method of manufacturing the semiconductor device according to the present embodiment will now be described referring to FIGS. 10 through 13.

First, the structure shown in FIG. 3 is obtained by the method of manufacturing the semiconductor device according to the aforementioned first preferred embodiment. Next, the electrode material 17 is polished from above by the CMP method to remove the electrode material 17 lying above the openings 6. As a result, the electrode material 17 lying above the upper surface of the insulating film 5 is removed, and the storage electrode 7 is formed in each of the openings 6 as shown in FIG. 10. Unlike the first preferred embodiment, the third preferred embodiment removes redundant portions of the electrode material 17 by the CMP method so that no needle projections will be formed on the top surface of the storage electrode 7.

Then, the structure shown in FIG. 10 is washed with hydrofluoric acid to remove an abrasive used in the above CMP method. Here, the hydrofluoric acid soaks into an interface between the BPTEOS film 4 and the storage electrode 7. The BPTEOS film 4 is easily etched by hydrofluoric acid while ruthenium composing the storage electrode 7 resists being etched by hydrofluoric acid. Accordingly, the BPTEOS film 4 lying in the vicinity of an interface with the top end of the storage electrode 7 is etched, creating a clearance 70 between the BPTEOS film 4 and the storage electrode 7 as shown in FIG. 11. The thickness of the dielectric film 8 of the MIM capacitor 10 lying in the clearance 70 will be made thin when formed in this state, because the dielectric film 8 resists being formed in the clearance 70, resulting in a possible increase in leakage current of the MIM capacitor 10. The third preferred embodiment thus performs heat treatment in a hydrogen atmosphere on the structure shown in FIG. 11 to eliminate the clearance 70 created between the BPTEOS film 4 and the storage electrode 7, thereby reducing the leakage current of the MIM capacitor 10. This process will now be discussed in detail.

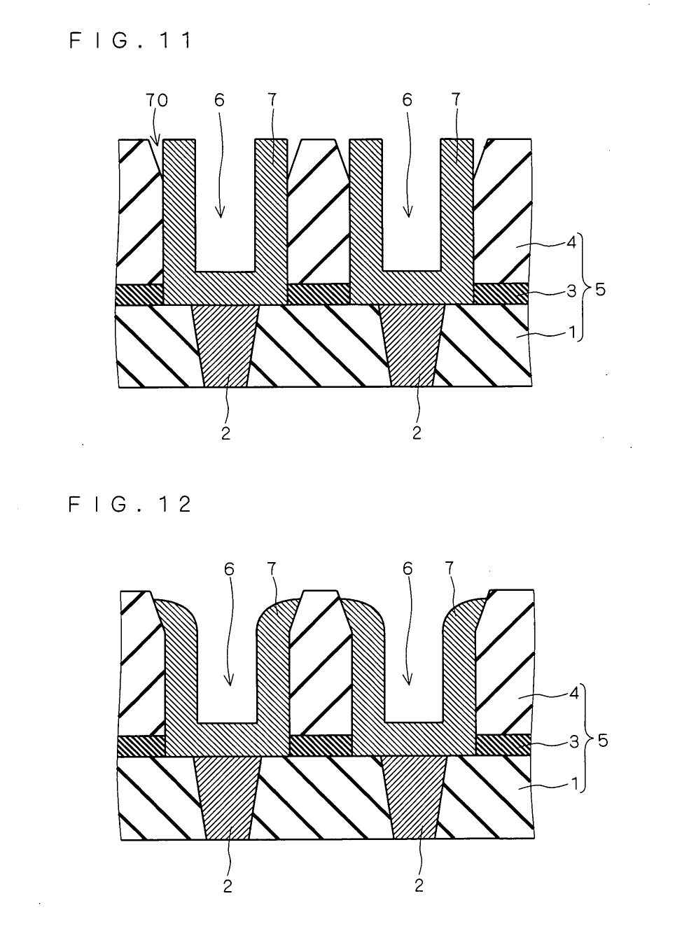

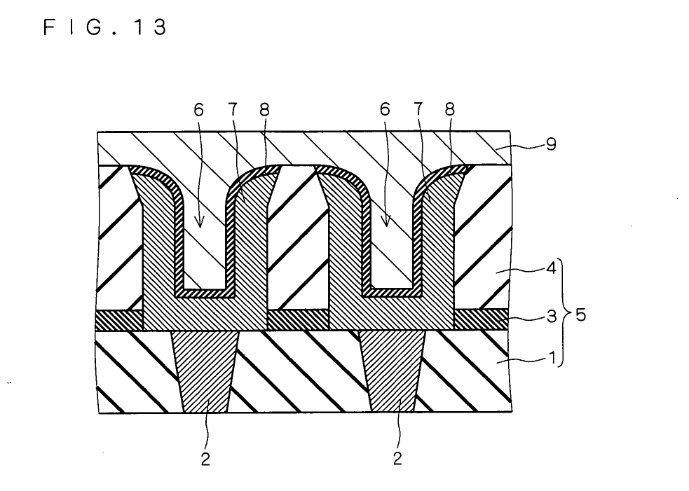

Heat treatment is performed in a hydrogen atmosphere on the structure shown in FIG. 11, for thirty seconds at a temperature of 700° C., for example. In the above CMP method, in which the redundant portions of the electrode material 17 are removed with the surface being oxidized, minute oxide films made of ruthenium tetroxide are formed scatteredly on the surface of the storage electrode 7. The heat treatment in the hydrogen atmosphere discussed above reduces those oxide films with hydrogen and remove them, causing migration in ruthenium composing the storage electrode 7. As a result, as shown in FIG. 12, the top ends of the storage electrode 7 tilt outwardly, bringing the BPTEOS film 4 and the storage electrode 7 in tight contact again. The clearance 70 is thus not created between the BPTEOS film 4 and the storage electrode 7. Therefore, the dielectric film 8 having a uniform thickness can be easily formed, allowing a reduction in leakage current of the MIM capacitor 10. In the meantime, the heat treatment in the hydrogen atmosphere enlarges the grains of ruthenium composing the storage electrode 7.

Next, as shown in FIG. 13, in the same manner as the first preferred embodiment, the dielectric film 8 and the plate electrode 9 are successively formed on the storage electrode 7, thereby completing the MIM capacitor 10. Thereafter, in the same manner as the first preferred embodiment, a BPTEOS film, an aluminum wiring and a passivation film all of which are not shown are successively formed, thereby completing a semiconductor device including a DRAM memory cell having the MIM capacitor 10.

As explained above, in the method of manufacturing the semiconductor device according to the third preferred embodiment, heat treatment is performed in a hydrogen atmosphere after forming the storage electrode 7. Accordingly, the oxide films that are formed on the surface of the storage electrode 7 as in the third preferred embodiment can be reduced and removed, causing migration in the storage electrode 7. Consequently, the clearance 70 that may be created between the storage electrode 7 and the BPTEOS film 4 when the abrasive used in the CMP method is removed can be altered in shape by the caused migration in the storage electrode 7, bringing the BPTEOS film 4 and the storage electrode 7 in tight contact to each other. Therefore, the above clearance 70 is eliminated, allowing a reduction in leakage current of the MIM capacitor 10.

Besides, when the storage electrode 7 is brought in tight contact with the BPTEOS film 4 due to the heat treatment in the hydrogen atmosphere, the top ends of the storage electrode 7 tilt outwardly. Accordingly, the opening areas of the openings 6 before forming the dielectric film 8 are enlarged as shown in FIG. 12. Therefore, the dielectric film 8 and the plate electrode 9 can be easily formed uniformly, allowing a reduction in leakage current of the MIM capacitor 10.

While the invention has been shown and described in detail, the foregoing description is in all aspects illustrative and not restrictive. It is therefore understood that numerous modifications and variations can be devised without departing from the scope of the invention.

1. A method of manufacturing a semiconductor device comprising a capacitor including a storage electrode, a dielectric film and a plate electrode, comprising the steps of:
(a) forming an insulating film;
(b) forming a plurality of openings in said insulating film that open toward an upper surface of said insulating film;
(c) forming a film of an electrode material made of metal on a surface of each of said openings and said upper surface of said insulating film;
(d) etching back said electrode material by performing dry etching thereon, to form a storage electrode made of said electrode material in each of said openings;
(e) performing wet etching on said storage electrode;
(f) forming a dielectric film on said storage electrode after said step (e); and
(g) forming a plate electrode on said dielectric film.

2. A method of manufacturing a semiconductor device comprising a capacitor including a storage electrode, a dielectric film and a plate electrode, comprising the steps of:
(a) forming an insulating film;
(b) forming a plurality of openings in said insulating film that open toward an upper surface of said insulating film;
(c) forming a film of an electrode material made of metal on a surface of each of said openings and said upper surface of said insulating film;
(d) performing heat treatment in a hydrogen atmosphere on said electrode material;
(e) etching back said electrode material by performing dry etching thereon, to form a storage electrode made of said electrode material in each of said openings after said step (d);
(f) forming a dielectric film on said storage electrode; and
(g) forming a plate electrode on said dielectric film.

3. A method of manufacturing a semiconductor device comprising a capacitor including a storage electrode, a dielectric film and a plate electrode, comprising the steps of:
(a) forming an insulating film;
(b) forming a plurality of openings in said insulating film that open toward an upper surface of said insulating film;
(c) forming a film of an electrode material made of metal on a surface of each of said openings and said upper surface of said insulating film;
(d) polishing said electrode material from above with an abrasive to remove said electrode material lying on said upper surface of said insulating film, thereby forming a storage electrode made of said electrode material in each of said openings;
(e) removing said abrasive that adheres to a structure obtained by performing said step (d);
(f) performing heat treatment in a hydrogen atmosphere on a structure obtained by performing said step (e);
(g) forming a dielectric film on said storage electrode after said step (f); and
(h) forming a plate electrode on said dielectric film.
